(19) United States
(12) Patent Application Publication
(10) Pub. No.: US 2025/0212482 A1
(43) Pub. Date: Jun. 26, 2025

(54) PASS-THROUGH STRUCTURES

(71) Applicant: QUALCOMM Incorporated, San Diego, CA (US)

(72) Inventors: Shreesh NARASIMHA, Charlotte, NC (US); Yan SUN, San Diego, CA (US); Deepak SHARMA, San Diego, CA (US)

(21) Appl. No.: 18/391,137

(22) Filed: Dec. 20, 2023

(51) Int. Cl. H01L 29/417; H01L 23/528

(52) U.S. Cl. CPC H10D 64/254; H01L 23/5286

(57) ABSTRACT

A chip includes a first transistor including a first source/drain, a second source/drain, a gate between the first source/drain and the second source/drain, and a first backside contact coupled to a bottom surface of the first source/drain. The chip also includes a pass-through structure including a first diffusion region extending in a first direction, a second backside contact coupled to a bottom surface of the first diffusion region, and a topside contact coupled to a top surface of the first diffusion region. The chip also includes a backside metal routing coupled between the first backside contact and the second backside contact.

### BACKGROUND

### Field

Aspects of the present disclosure relate generally to chip layout, and more particularly, to pass-through structures that provide signal routing between a backside metal layer and a topside metal layer.

### Background

A chip may include many cells (e.g., thousands to millions of cells) laid out on the chip. Each cell may include one or more transistors that are arranged to provide a circuit (e.g., a driver, a logic gate, combinational logic, a latch, or another type of circuit). The chip may also include multiple metal layers that may be patterned (e.g., using lithography and etching) to provide signal routing for the cells.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first transistor including a first source/drain, a second source/drain, a gate between the first source/drain and the second source/drain, and a first backside contact coupled to a bottom surface of the first source/drain. The chip also includes a pass-through structure including a first diffusion region extending in a first direction, a second backside contact coupled to a bottom surface of the first diffusion region, and a topside contact coupled to a top surface of the first diffusion region. The chip also includes a backside metal routing coupled between the first backside contact and the second backside contact.

A second aspect relates to a chip. The chip includes a first transistor including a first source/drain, a second source/drain, a gate between the first source/drain and the second source/drain, and a backside contact coupled to a bottom surface of the first source/drain. The chip also includes a pass-through structures, a backside metal routing coupled to the backside contact and extending under the first transistor to the pass-through structures, and a topside metal line extending over the pass-through structures. The pass-through structures are coupled in parallel between the backside metal routing and the topside metal line, and each of the pass-through structures provides a respective signal path between the backside metal routing and the topside metal line.

A third aspect relates to a chip. The chip includes a first transistor including a first source/drain, a second source/drain, a gate between the first source/drain and the second source/drain, and a backside contact coupled to a bottom surface of the first source/drain. The chip also includes a pass-through structure including a first diffusion region extending in a first direction, a second backside contact coupled to a bottom surface of first diffusion region, a first topside contact coupled to a top surface of the first diffusion region, a third backside contact coupled to the bottom surface of the first diffusion region, and a second topside contact coupled to the top surface of the first diffusion region. The chip also includes a backside metal routing coupled to the first backside contact, the second backside contact, and the third backside contact, wherein the backside metal routing extends under the first transistor to the pass-through structure. The chip also includes a topside metal line extending in the first direction, wherein the topside metal line is coupled to the first topside contact and the second topside contact.

A fourth aspect relates to a chip. The chip includes a first cell including a first diffusion region extending in a first direction, gates formed over the first diffusion region, wherein each of the gates is elongated and extends in a second direction perpendicular to the first direction, and a first backside contact coupled to a bottom surface of the first diffusion region. The chip also includes a pass-through filler cell including a second diffusion region, a second backside contact coupled to a bottom surface of the second diffusion region, and a topside contact coupled to a top surface of the second diffusion region. The chip also includes a backside metal routing coupled between the first backside contact and the second backside contact.

A fifth aspect relates to a chip. The chip includes a first cell including a first diffusion region extending in a first direction, gates formed over the first diffusion region, wherein each of the gates is elongated and extends in a second direction perpendicular to the first direction, and a first backside contact coupled to a bottom surface of the first diffusion region. The chip also includes a pass-through filler cell including a second diffusion region, a second backside contact coupled to a bottom surface of the second diffusion region, a first topside contact coupled to a top surface of the second diffusion region, a third backside contact coupled to the bottom surface of the second diffusion region, and a second topside contact coupled to the top surface of the second diffusion region. The chip also includes a backside metal routing coupled to the first backside contact, the second backside contact, and the third backside contact, wherein the backside metal routing extends under the first cell to the pass-through filler cell. The chip also includes a topside metal line extending in the first direction, wherein the topside metal line is coupled to the first topside contact and the second topside contact.

### BRIEF DESCRIPTION OF THE DRAWINGS

FIG. 1A shows a side view of an example of a chip including a transistor, multiple topside layers, and multiple backside layers according to certain aspects of the present disclosure.

FIG. 1B shows a side view of the chip of FIG. 1A further including a via disposed between a backside contact and a backside metal layer according to certain aspects of the present disclosure.

FIG. 1C shows a side view of the transistor of FIG. 1A implemented with a gate-all-around field effect transistor according to certain aspects of the present disclosure.

FIG. 1D shows a side view of the chip of FIG. 1C further including a via disposed between a backside contact and a backside metal layer according to certain aspects of the present disclosure.

FIG. 2 shows an example of a cell and exemplary signal routing for the cell formed from a first topside metal layer and a second topside metal layer according to certain aspect of the present disclosure.

FIG. 3 shows an example of a row of cells illustrating examples of intra cell obstruction and neighbor cell obstruction according to certain aspects of the present disclosure.

FIG. 4A shows an example of a pass-through filler cell in the row of cells according to certain aspects of the present disclosure.

FIG. 4B shows an example of topside metal lines coupled to the pass-through filler cell shown in FIG. 4A according to certain aspects of the present disclosure.

FIG. 5A shows an example of the pass-through filler cell at another location in the row of cells according to certain aspects of the present disclosure.

FIG. 5B shows an example of topside metal lines coupled to the pass-through filler cell shown in FIG. 5A according to certain aspects of the present disclosure.

FIG. 6 shows a top view of an exemplary layout of diffusion regions and gates for a first cell, the pass-through filler cell, and a second cell according to certain aspects of the present disclosure.

FIG. 7A shows a top view of an example of a backside metal routing extending from a first cell to a pass-through structure in a pass-through filler cell according to certain aspects of the present disclosure.

FIG. 7B shows an example of the pass-through structure including a backside contact coupling the backside metal routing to the pass-through structure according to certain aspects of the present disclosure.

FIG. 7C shows an example of the pass-through structure including a topside contact according to certain aspects of the present disclosure.

FIG. 7D shows an example of a topside metal line extending over the pass-through structure and coupled to the topside contact of the pass-through structure according to certain aspects of the present disclosure.

FIG. 7E shows a cross-sectional view of the pass-through structure of FIG. 7D according to certain aspects of the present disclosure.

FIG. 8A shows another example of the pass-through structure including a backside contact coupling the backside metal routing to the pass-through structure according to certain aspects of the present disclosure.

FIG. 8B shows another example of the pass-through structure including a topside contact according to certain aspects of the present disclosure.

FIG. 8C shows another example of the topside metal line extending over the pass-through structure and coupled to the topside contact of the pass-through structure according to certain aspects of the present disclosure.

FIG. 8D shows a cross-sectional view of the pass-through structure of FIG. 8C according to certain aspects of the present disclosure.

FIG. 9A shows yet another example of the pass-through structure including a backside contact coupling the backside metal routing to the pass-through structure according to certain aspects of the present disclosure.

FIG. 9B shows yet another example of the pass-through structure including a topside contact according to certain aspects of the present disclosure.

FIG. 9C shows yet another example of the topside metal line extending over the pass-through structure and coupled to the topside contact of the pass-through structure according to certain aspects of the present disclosure.

FIG. 9D shows a cross-sectional view of the pass-through structure of FIG. 9C according to certain aspects of the present disclosure.

FIG. 10A shows an example of a first pass-through structure including a first backside contact and a second pass-through structure including a second backside contact according to certain aspects of the present disclosure.

FIG. 10B shows an example of the first pass-through structure including a first topside contact and the second pass-through structure including a second topside contact according to certain aspects of the present disclosure.

FIG. 10C shows an example of a topside metal line extending over the first pass-through structure and the second pass-through structure according to certain aspects of the present disclosure.

FIG. 11 is a block diagram illustrating a computer system according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

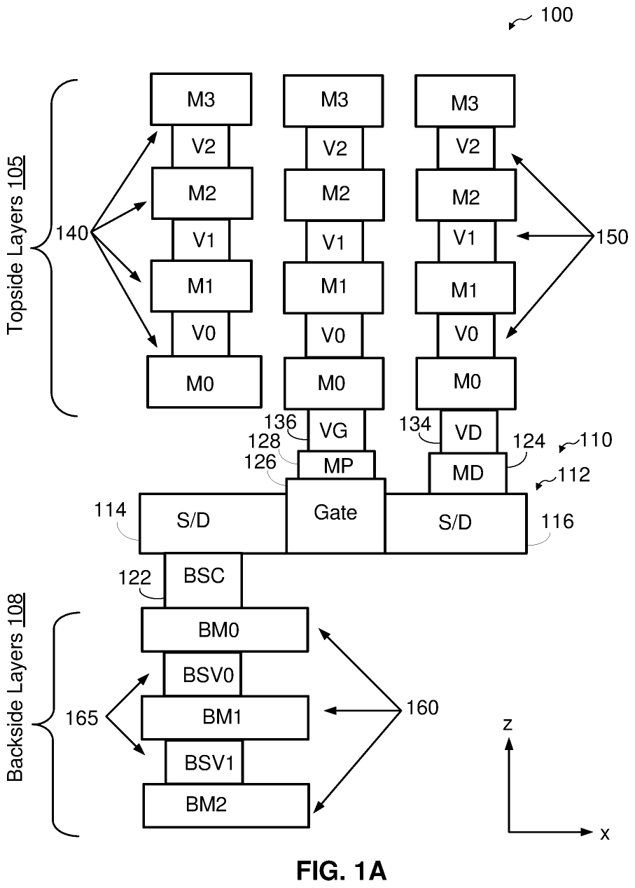

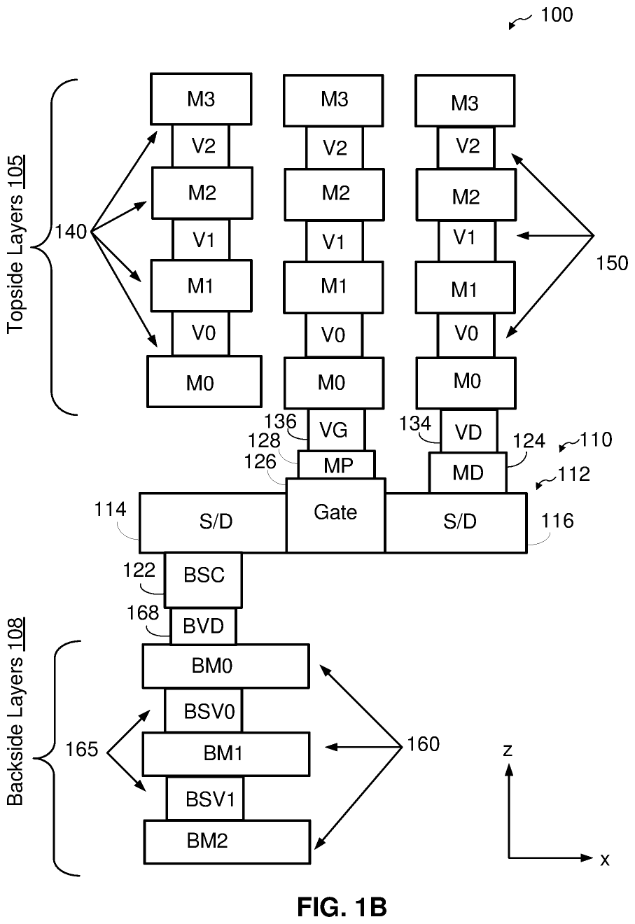

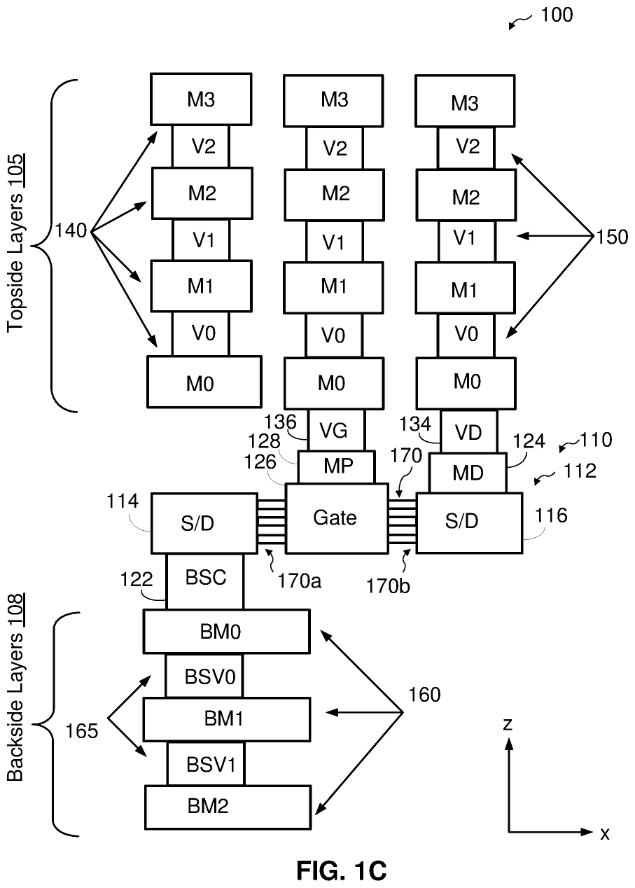

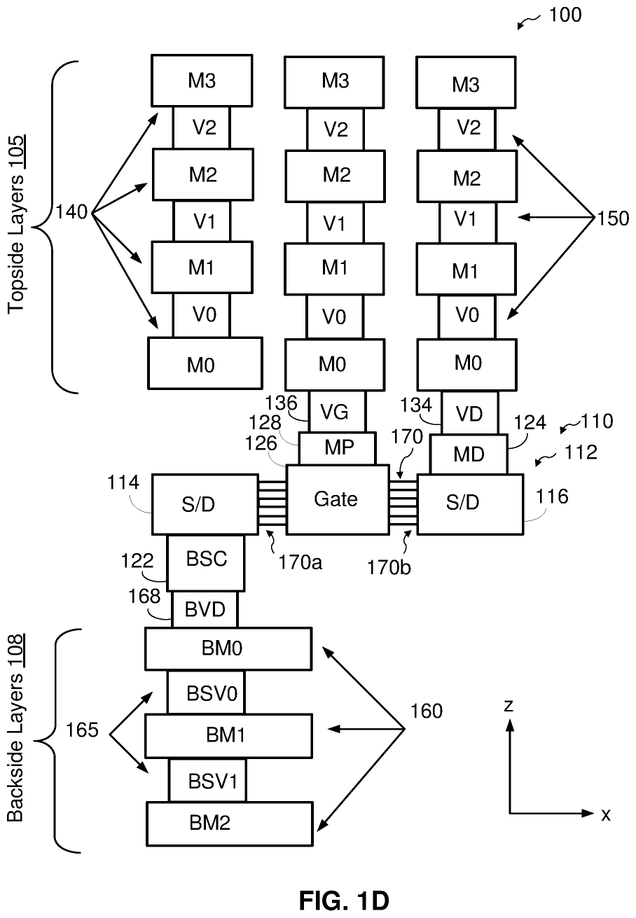

FIG. 1A shows a side view of an example of a chip 100 (e.g., a die) including a transistor 110, multiple topside layers 105, and multiple backside layers 108 according to certain aspects. Although one transistor 110 is shown in FIG. 1A for simplicity, it is to be appreciated that the chip 100 includes many transistors and other devices. As discussed further below, the transistor 110 may be implemented using a fin field-effect transistor (FinFET) process, a gate-all-around FET process, or another type of process. The topside layers 105 include layers above the transistor 110, and the backside layers 108 include layers below the transistor 110. The topside layers may also be referred to as frontside layers or another term.

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may include polysilicon, a gate metal, and/or another gate material. In the example shown in FIG. 1A, a portion of the diffusion region 112 to the left of the gate 126 provides a first source/drain 114 of the transistor 110, and a portion of the diffusion region 112 to the right of the gate 126 provides a second source/drain 116 of the transistor 110. As used herein, the term “source/drain” means a source, a drain, or both a source and a drain. In this example, the gate 126 controls the conductivity between the first source/drain 114 and the second source/drain 116 based on a voltage applied to the gate 126. The transistor 110 may be a p-type transistor in which the diffusion region 112 is a p-type diffusion region, or the transistor 110 may be an n-type transistor in which the diffusion region 112 is an n-type diffusion region.

In this example, the chip 100 includes a topside contact 124 formed on a top surface of the second source/drain 116. A top surface may also be referred to as a frontside surface. The contact 124 may be formed (i.e., patterned) from a topside contact layer using, for example, lithographic and etching processes. The contact 124 may be referred to as a metal-diffusion (MD) contact, contact active (CA), or another term. The chip 100 may also include a gate contact 128 formed on the gate 126. The gate contact 128 may be referred to as a metal-poly (MP) contact or another term. The gate contact 128 may be omitted in some implementations.

In this example, the topside layers 105 include topside metal layers 140. A topside metal layer may also be referred to as a frontside metal layer, a metal interconnect, or another term. The topside metal layers 140 may be patterned (e.g., using lithography and etching) to provide signal routing for the transistor 110 and other transistors (not shown in FIG. 1A) integrated on the chip 100. In some implementations, the topside metal layers 140 may also be patterned to form a power distribution network including supply rails for distributing power to the transistor 110 and other transistors integrated on the chip 100. In other implementations, the power distribution network is provided using the backside layers 108 (e.g., to reduce routing congestion in the topside layers 105), as discussed further below.

In the example in FIG. 1A, the bottom-most topside metal layer among the topside metal layers 140 is referred to as metal layer M0. The topside metal layer immediately above metal layer M0 is referred to as metal layer M1, the topside metal layer immediately above metal layer M1 is referred to as metal layer M2, the topside metal layer immediately above metal layer M2 is referred to as metal layer M3, and so forth. Although four topside metal layers 140 (i.e., M0 to M3) are shown in FIG. 1A for ease of illustration, it is to be appreciated that the topside layers 105 may include additional topside metal layers above metal layer M3. It is to be appreciated that the present disclosure is not limited to the nomenclature in which the bottom-most topside metal layer is referred to as metal layer M0. For instance, in another example, the bottom-most topside metal layer may be referred to as metal layer M1 instead of metal layer M0.

The topside layers 105 also includes vias 150 that provide coupling between the topside metal layers 140. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip also includes a via 136 disposed between the gate contact 128 and metal layer M0, in which the via 136 couples the gate contact 128 (and hence the gate 126) to metal layer M0. For implementations where the gate contact 128 is omitted, the via 136 may be disposed between the gate 126 and metal layer M0 without an intervening gate contact. Also, in this example, the chip 100 includes a via 134 disposed between the contact 124 and metal layer M0, in which the via 134 couples the contact 124 to metal layer M0. In some implementations, the via 134 may be omitted with the contact 124 directly contacting metal layer M0.

In certain aspects, the diffusion region 112 and the gate 126 of the transistor 110 and the topside layers 105 may be formed on a silicon substrate during fabrication. A carrier wafer (not shown) may then be bonded to the top of the chip 100 for structural support, and most or all of the silicon substrate may be grounded and/or polished off. The backside layers 108 may then be formed underneath the transistor 110 and/or any remaining portion of the silicon substrate.

In this example, the backside layers 108 include backside metal layers 160. The backside metal layers 160 may be patterned (e.g., using lithography and etching) to form a power distribution network including supply rails for distributing power to the transistor 110 and other transistors on the chip 100.

In the example in FIG. 1A, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1A for ease of illustration, it is to be appreciated that the backside layers 108 may include additional metal layers below backside metal layer BM2.

In the example in FIG. 1A, the chip 100 includes a backside contact 122 formed on a bottom surface (i.e., backside surface) of the first source/drain 114. The backside contact 122 may be formed (i.e., patterned) from a backside contact layer (labeled “BSC”) using, for example, lithographic and etching processes. The backside contact 122 is used to couple the first source/drain 114 to backside metal layer BM0. In some implementations, the backside contact 122 may directly contact backside metal layer BM0, as shown in the example in FIG. 1A. In other implementations, the backside contact 122 may be coupled to backside metal layer BM0 through an intervening via. In this regard, FIG. 1B shows an example in which the chip 100 includes a backside via 168 (labeled “BVD”) disposed between the backside contact 122 and backside metal layer BM0. In this example, the via 168 provides a space between the backside contact 122 and backside metal layer BM0 in the vertical direction (i.e., z direction in FIG. 1B).

In the examples in FIG. 1A and FIG. 1B, the backside layers 108 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 108 can significantly reduce routing congestion compared with using the topside layers 105 for both signal routing and power distribution. The reduced congestion allows the layout of the signal routing to be better optimized (e.g., to reduce parasitic capacitances for higher performance), and allows the layout of the power distribution network to be better optimized (e.g., to reduce resistances in the power distribution network for lower current-resistor (IR) drops).

As discussed above, the transistor 110 may be implemented using a FinFET process, a gate-all-around FET process, or another type of process. For the example of a FinFET process, the diffusion region 112 includes fins extending in the horizontal direction (i.e., x direction in FIGS. 1A and 1B), in which the gate 126 may surround each of the fins on three sides. FIG. 1C shows an example in which the transistor 110 is implemented using a gate-all-around FET process. In this example, the diffusion region 112 includes vertically stacked channels 170 (e.g., nanosheets) in which the gate 126 may surround each of the channels 170 on four sides. The first source/drain 114 and the second source/drain 116 may each include epitaxially grown or deposited silicon, a silicon-based material (e.g., silicon-germanium), or any combination thereof. In this example, the first source/drain 114 is coupled to a first side 170a of the channels 170, and the second source/drain 116 is coupled to a second side 170b of the channels. However, it is to be appreciated that the present disclosure is not limited to this example. FIG. 1D shows the exemplary transistor 110 of FIG. 1C in which the chip 100 includes the via 168 (labeled “BVD”) between the backside contact 122 and backside metal layer BM0. As discussed above, the via 168 provides a space between the backside contact 122 and backside metal layer BM0.

Although one gate 126 is shown in FIGS. 1A, 1B, 1C, and 1D, it is to be appreciated that the transistor 110 may include multiple gates arranged in parallel and coupled to one another (e.g., through metal layer M0). A transistor with multiple gates may be referred to as a multi-finger transistor or another term.

Transistors on the chip 100 may be organized into cells. Each cell may include one or more transistors that are arranged to provide a circuit (e.g., a driver, a logic gate, combinational logic, a latch, a flip-flop, or another type of circuit). The cells may be arranged in rows on the chip 100, in which each row of cells may be between a supply rail and a ground rail to deliver power to the cells in the row.

The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates (e.g., poly gates), diffusion regions, and contacts in the cell. The standard cell library may also specify the layouts of filler cells, decap cells, endcap cells, and the like.

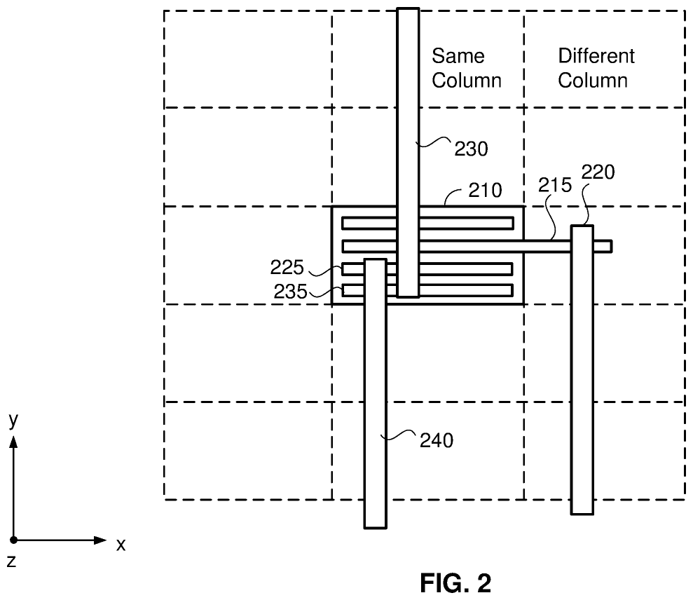

FIG. 2 shows a top view of a cell 210 that may be placed on the chip 100. Although one cell 210 is shown in FIG. 2 for simplicity, it is to be appreciated that the chip 100 may include many cells (e.g., arranged in rows and/or columns). FIG. 2 shows an example of signal routing for the cell 210 using topside metal layers M0 and M1.

More particularly, FIG. 2 shows an example of metal lines 215, 225, and 235 formed (i.e., patterned) from metal layer M0 to provide signal routing for the cell 210 in metal layer M0. The metal lines 215, 225, and 235 extend in the x direction, and therefore provide signal routing in the x direction. Each of the metal lines 215, 225, and 235 may be coupled to a gate or a source/drain contact in the cell 210 by a via (e.g., via VG or VD in FIGS. 1A to 1D).

FIG. 2 also shows an example of metal lines 220, 230, and 240 formed (i.e., patterned) from metal layer M1 to provide signal routing for the cell 210 in metal layer M1. The metal lines 220, 230, and 240 extend in the y direction, and therefore provide signal routing in the y direction.

In this example, metal lines 230 and 240 provide signal routing for the cell 210 within the same column in which the cell 210 resides. The metal line 230 is coupled to the metal line 235 by a via (e.g., via V0 in FIGS. 1A to 1D) and the metal line 240 is coupled to the metal line 225 by a via (e.g., via V0 in FIGS. 1A to 1D). However, in some cases, signal routing for the cell 210 in metal layer M1 within the same column as the cell 210 may cause a bottleneck for routing resources in metal layer M1. For example, signal routing for the cell 210 in metal layer M1 may create an obstruction for signal routing in metal layer M1 for another cell (not shown) residing in the same column as the cell 210.

To provide greater flexibility in routing signals for the cell 210 in metal layer M1 and alleviate routing congestion in metal layer M1, layout techniques have been developed to allow a metal line in metal layer M1 to access the cell 210 from a different column. In this regard, FIG. 2 shows an example in which the metal line 220 accesses the cell 210 from a different column. This is achieved by extending the metal line 215 in the x direction to a neighbor cell, and coupling the metal line 220 to the metal line 215 over the neighbor cell.

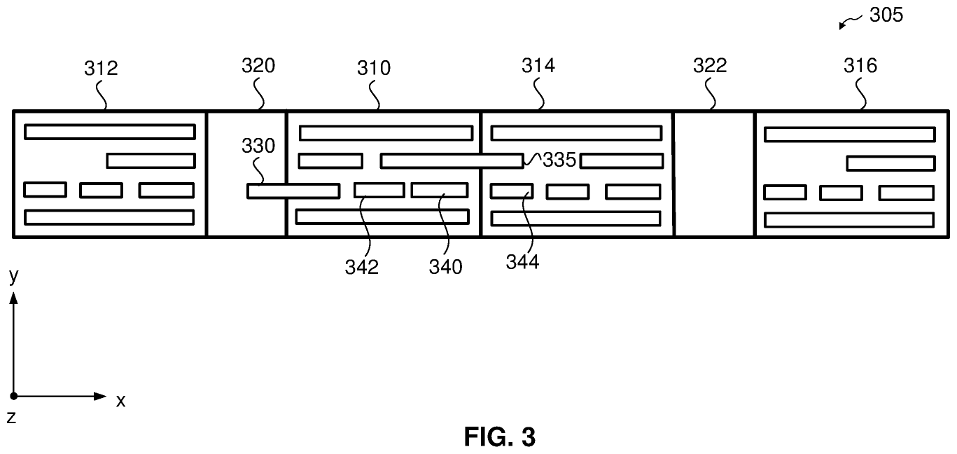

However, a challenge with using the above techniques is that it is not always possible to extend a metal line in metal layer M0 to a neighbor cell due to obstructions in metal layer M0. Examples of obstructions in metal layer M0 are illustrated in FIG. 3, as discussed further below.

FIG. 3 shows an example of a row of cells 305 including a first cell 310, a second cell 312, a third cell 314, and a fourth cell 316. Each of the cells 310, 312, 314, and 316 may provide a logic gate, a driver, a latch, combinational logic, or another type of circuit. In this example, the row of cells 305 also includes a first filler cell 320 located between first cell 310 and the second cell 312, and a second filler cell 322 located between the third cell 314 and the fourth cell 316. In this example, each of the filler cells 320 and 322 may be a non-functioning cell that provides a space between cells in the x direction.

FIG. 3 also shows an example of metal lines formed (i.e., patterned) from metal layer M0 to provide signal routing for the cells 310, 312, 314, and 316 in metal layer M0. The metal lines in metal layer M0 includes metal lines 330, 335, 340, and 342 for providing signal routing for the first cell 310. In this example, the metal line 330 extends to the first filler cell 320, which provides a metal line (not shown) in metal layer M1 with access to the metal line 330 outside the same column as the first cell 310. Also in this example, the metal line 335 extends to a neighbor cell (i.e., the third cell 314), which provides a metal line (not shown) in metal layer M1 with access to the metal line 335 outside the same column as the first cell 310.

However, the metal line 340 is blocked from extending to the first filler cell 320 and blocked from extending to the neighbor cell (i.e., the third cell 314). More particularly, the metal line 340 is blocked from extending to the first filler cell 320 by the metal line 342. In this example, the metal line 342 may be referred to as an intra cell obstruction since the metal line 342 corresponds to the same cell as the metal line 340. The metal line 340 is blocked from extending to the neighbor cell (i.e., the third cell 314) by metal line 344, which provides signal routing for the neighbor cell. In this example, the metal line 344 may be referred to as a neighbor cell obstruction since the metal line 344 corresponds to the neighbor cell. Thus, in this example, the metal line 340 is blocked from extending to the first filler cell 320 by an intra cell obstruction and blocked from extending to the neighbor cell by a neighbor cell obstruction.

To address the above, aspects of the present disclosure provide a pass-through filler cell configured to pass a signal between a backside metal layer (e.g., backside metal layer BM0) and a topside metal layer (e.g., topside metal layer M0). This allows signals for a cell (e.g., the first cell 310) to be routed under the cell to the pass-through filler cell using the backside metal layer, which avoids obstructions in the topside metal layer. The above features and other features of the present disclosure are discussed further below.

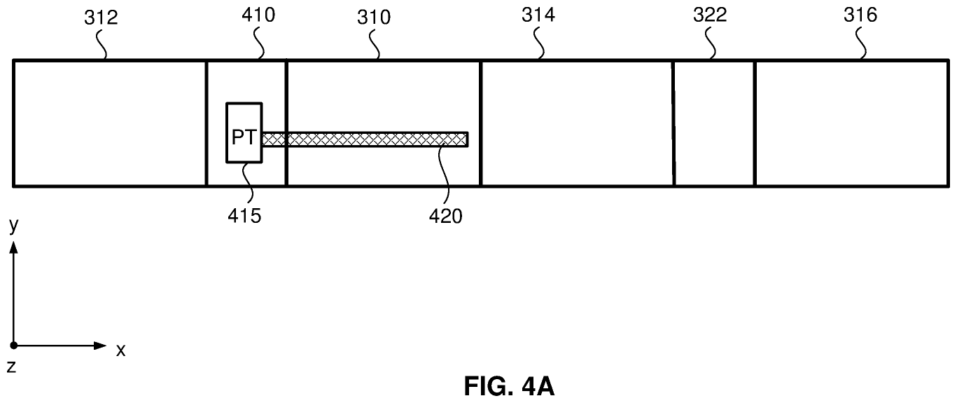

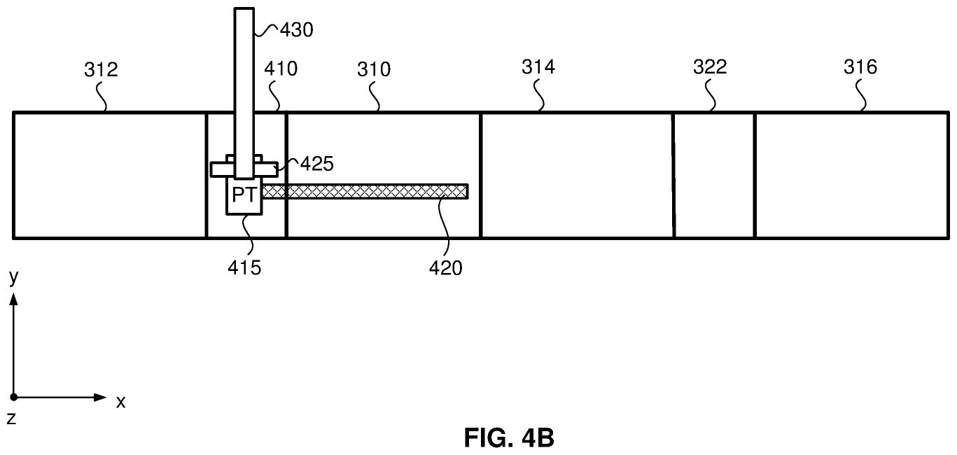

FIG. 4A shows an example of a pass-through filler cell 410 according to certain aspects of the present disclosure. The pass-through filler cell 410 includes pass-through structure 415 configured to pass signals between backside metal layer BM0 and topside metal layer M0. The pass-through structure 415 may include a backside contact (e.g., formed from backside contact layer BSC shown in FIGS. 1A to 1D), one or more diffusion regions, and a topside contact (e.g., formed from topside contact layer MD shown in FIGS. 1A to 1D). Exemplary implementations of the pass-through structure 415 are discussed below. A topside contact may also be referred to as a frontside contact or another term.

FIG. 4A shows an example in which the pass-through filler cell 410 is located between the first cell 310 and the second cell 312. FIG. 4A also shows an example of backside metal routing 420 extending from the first cell 310 to the pass-through structure 415, and passing under the first cell 310. The backside metal routing 420 may include a backside metal line extending in the x direction and formed (i.e., patterned) from backside metal layer BM0. Since the backside metal routing 420 passes under the first cell 310, the backside metal routing 420 avoids obstructions (e.g., intra cell obstructions) in metal layer M0. Note that the topside metal lines shown in FIG. 3 are not shown in FIG. 4A in order to show the backside metal routing 420 more clearly.

The backside metal routing 420 (e.g., backside metal line) may be coupled to a gate or a source/drain in the first cell 310 through a backside contact (e.g., e.g., formed from backside contact layer BSC shown in FIGS. 1A to 1D) coupled to a bottom surface of the gate or the source/drain. In this example, the backside metal routing 420 is coupled between the pass-through structure 415 and the gate and/or source/drain in the first cell 310.

FIG. 4B shows an example of a metal line 425 in metal layer M0 extending in the x direction and coupled to the pass-through structure 415. In this example, the pass-through structure 415 provides a signal path between the backside metal routing 420 and the metal line 425. FIG. 4B also shows an example of a metal line 430 in metal layer M1 and extending in the y direction. The metal line 430 may be coupled to the metal line 425 by a via (e.g., via V0), In this example, the pass-through structure 415 and the backside metal routing 420 allow the metal line 430 to access the first cell 310 outside the same column as the first cell 310 while avoiding obstructions in metal layer M0 (e.g., avoid intra cell obstructions in metal layer M0 (e.g., the metal line 342 in the example in FIG. 3).

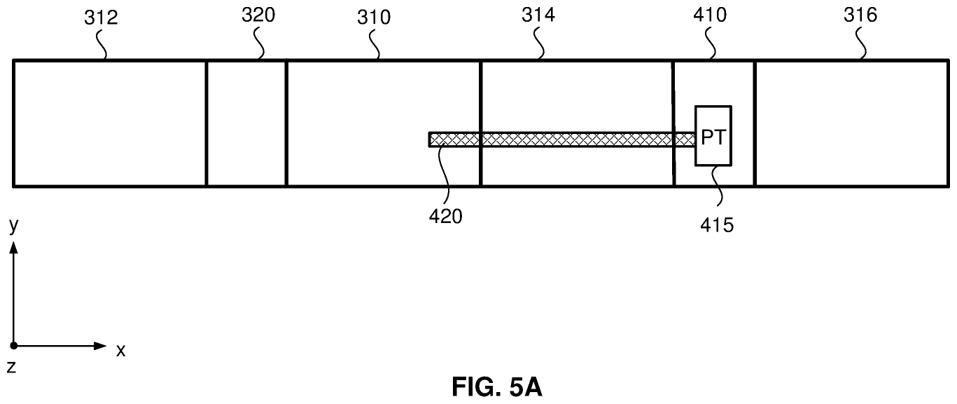

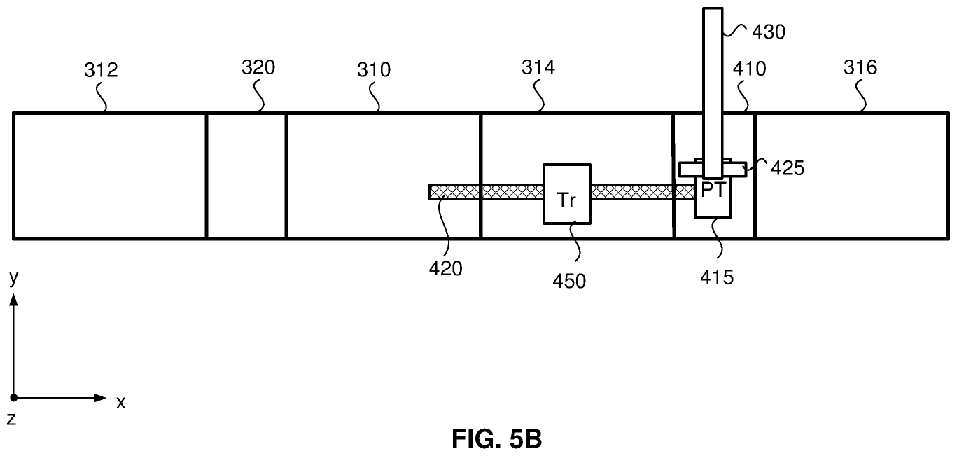

FIG. 5A shows an example in which the pass-through filler cell 410 is located between the third cell 314 and the fourth cell 316. In FIG. 5A, the backside metal routing 420 extends from the first cell 310 to the pass-through structure 415, and passes under the first cell 310 and the neighbor cell (i.e., the third cell 314). Since the backside metal routing 420 passes under the first cell 310 and the neighbor cell, the backside metal routing 420 avoids obstructions (e.g., neighbor cell obstructions) in metal layer M0. FIG. 5B shows an example of the metal line 425 in metal layer M0 coupled to the pass-through structure 415, and the metal line 430 in metal layer M1 coupled to the metal line 425. FIG. 5B also shows an example in which the backside metal routing passes under a transistor 450 in the third cell 314. The transistor 450 may be implemented with the exemplary transistor 110 shown in FIGS. 1A to 1D.

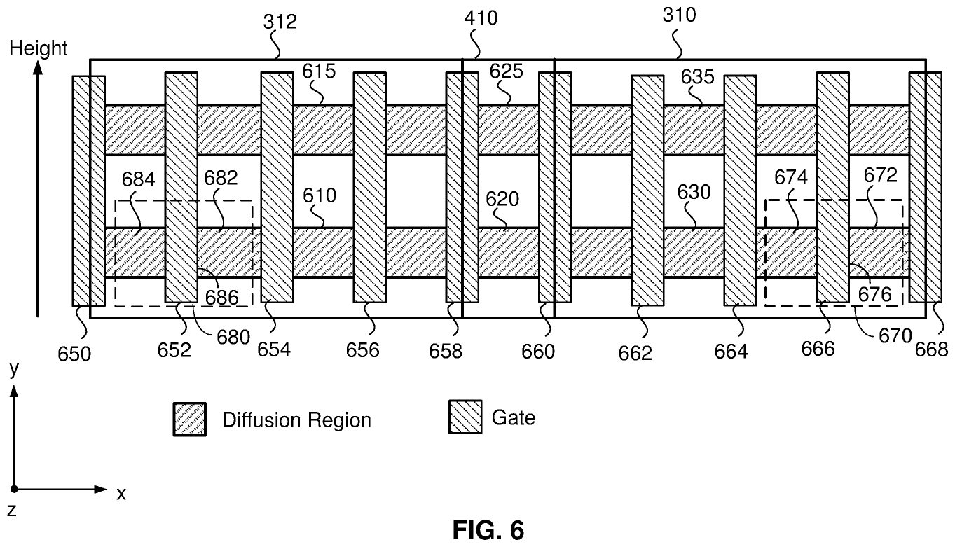

FIG. 6 shows a top view of an exemplary layout of diffusion regions and gates for the first cell 310, the pass-through filler cell 410, and the second cell 312 according to certain aspects of the present disclosure. In this example, the first cell 310 includes a first diffusion region 630 and a second diffusion region 635. Each of the diffusion regions 630 and 635 extends in the x direction, and the diffusion regions 630 and 635 are spaced apart from one another in the y direction. The first diffusion region 630 may be an n-type diffusion and the second diffusion region 635 may be a p-type diffusion region, or vice versa.

The second cell 312 includes a first diffusion region 610 and a second diffusion region 615. Each of the diffusion regions 610 and 615 extends in the x direction, and the diffusion regions 610 and 615 are spaced apart from one another in the y direction. The first diffusion region 610 may be an n-type diffusion and the second diffusion region 615 may be a p-type diffusion region, or vice versa.

The pass-through filler cell 410 includes a first diffusion region 620 and a second diffusion region 625. Each of the diffusion regions 620 and 625 extends in the x direction, and the diffusion regions 620 and 625 are spaced apart from one another in the y direction. The first diffusion region 620 may be an n-type diffusion and the second diffusion region 625 may be a p-type diffusion region, or vice versa.

FIG. 6 shows an example of gates 650, 652, 654, 656, 658, 660, 662, 664, 666, and 668 where each of the gates 650, 652, 654, 656, 658, 660, 662, 664, 666, and 668 is elongated and extends in the y direction. The gates 650, 652, 654, 656, 658, 660, 662, 664, 666, and 668 are spaced apart from one another in the x direction. For example, the 650, 652, 654, 656, 658, 660, 662, 664, 666, and 668 may be spaced apart from one another by a uniform pitch. Each of the gates 650, 652, 654, 656, 658, 660, 662, 664, 666, and 668 may include polysilicon, a gate metal, another gate material, or any combination thereof.

In the example in FIG. 6, the gates 662, 664, and 666 extend across the first diffusion region 630 and the second diffusion region 635 of the first cell 310. The gates 662, 664, and 666 and the first diffusion region 630 in the first cell 310 may form one or more transistors in the first cell 310, in which portions of the first diffusion region 630 between the gates 662, 664, and 666 provide sources/drains of the one or more transistors. For example, a first transistor 670 may include at least a portion of the gate 666 to form a gate 676 of the first transistor 670. The first transistor 670 may also include at least a portion of the first diffusion region 630 to form a first source/drain 672 and a second source/drain 674, in which the gate 676 is between the first source/drain 672 and the second source/drain 674. It is to be appreciated that, in some implementations, the first transistor 670 may also include at least a portion of one or more of the gates 664 and 662 for a multi-finger implementation of the first transistor 670.

The gates 662, 664, and 666 and the second diffusion region 635 in the first cell 310 may also form one or more transistors in the first cell 310, in which portions of the second diffusion region 635 between the gates 662, 664, and 666 provide sources/drains of the one or more transistors. In certain aspects, the first diffusion region 630 may be an n-type diffusion region to provide one or more n-type field effect transistors (NFETs) and the second diffusion region 635 may be a p-type diffusion region to provide one or more p-type field effect transistors (PFETs), or vice versa.

In the example in FIG. 6, the gates 652, 654, and 656 extend across the first diffusion region 610 and the second diffusion region 615 of the second cell 312. The gates 652, 654, and 656 and the first diffusion region 610 in the second cell 322 may form one or more transistors in the second cell 312, in which portions of the first diffusion region 610 between the gates 652, 654, and 656 provide sources/drains of the one or more transistors. For example, a second transistor 680 may include at least a portion of the gate 652 to form a gate 686 of the second transistor 680. The first transistor 680 may also include at least a portion of the first diffusion region 610 to form a first source/drain 682 and a second source/drain 684, in which the gate 686 is between the first source/drain 682 and the second source/drain 684. It is to be appreciated that, in some implementations, the second transistor 680 may also include at least a portion of one or more of the gates 654 and 656 for a multi-finger implementation of the first transistor 680.

The gates 652, 654, and 656 and the second diffusion region 615 in the second cell 312 may also form one or more transistors in the second cell 312, in which portions of the second diffusion region 615 between the gates 652, 654, and 656 provide sources/drains of the one or more transistors. In certain aspects, the first diffusion region 610 may be an n-type diffusion region to provide one or more n-type field effect transistors (NFETs) and the second diffusion region 615 may be a p-type diffusion region to provide one or more p-type field effect transistors (PFETs), or vice versa.

The gate 650 lies on a left boundary of the second cell 312, the gate 658 lies on a boundary between the pass-through filler cell 410 and the second cell 312, the gate 660 lies on a boundary between the pass-through filler cell 410 and the first cell 310, and the gate 668 lies on a right boundary of the first cell 310. However, it is to be appreciated that the present disclosure is not limited to this example. In certain aspects, the gates 650, 658, 660, and 668 on the cell boundaries may be dummy gates. The chip 100 may include a single diffusion break (SDB) or a double diffusion break (DDB) at each cell boundary to separate the diffusion regions 610, 615, 620, 625, 630, and 635 of the cells 310, 312, and 410.

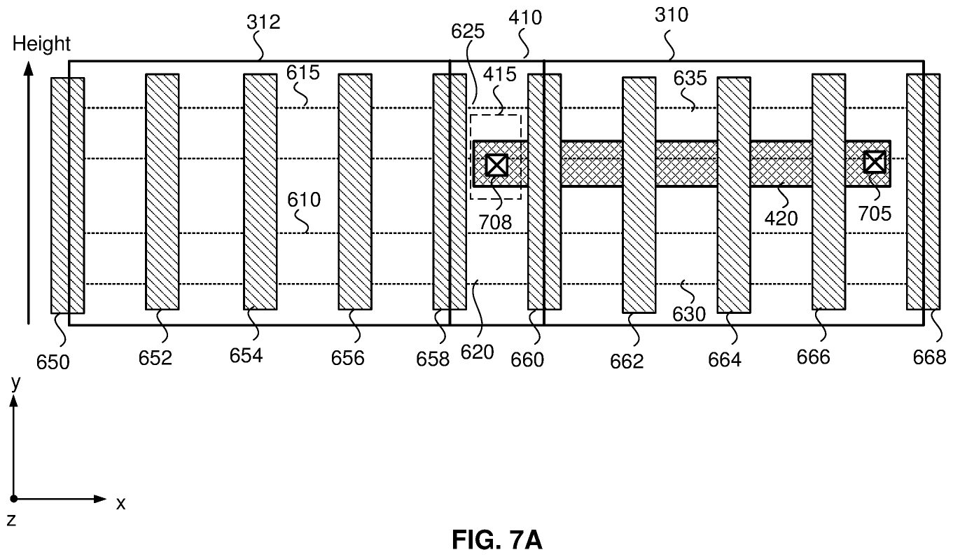

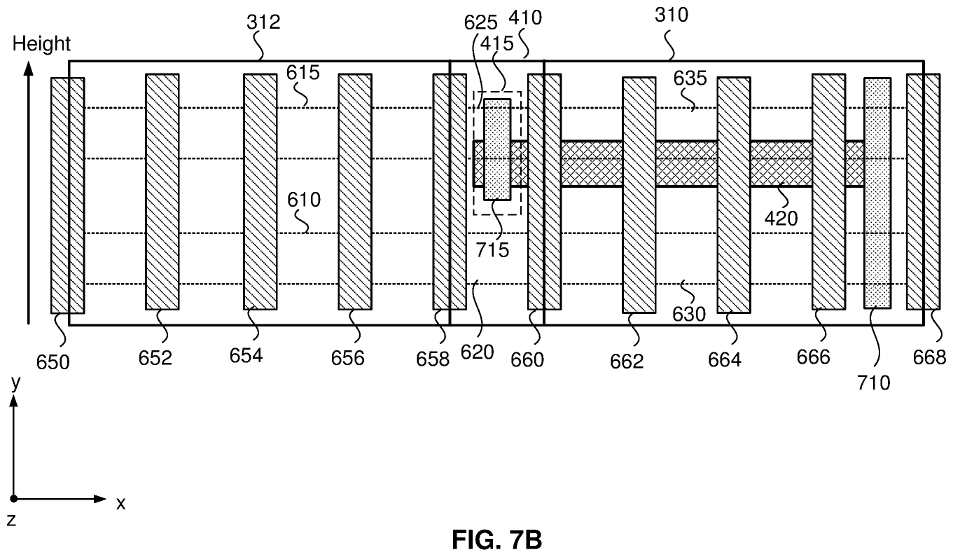

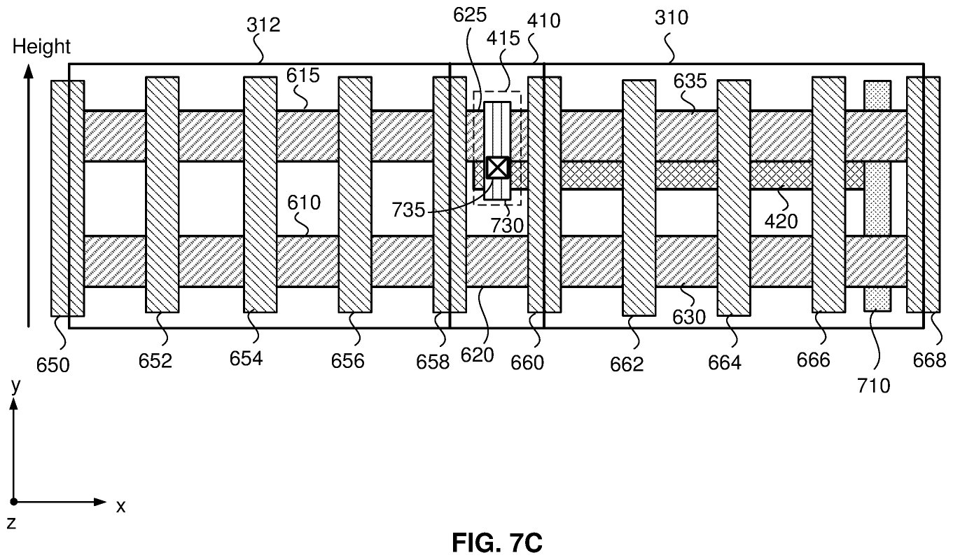

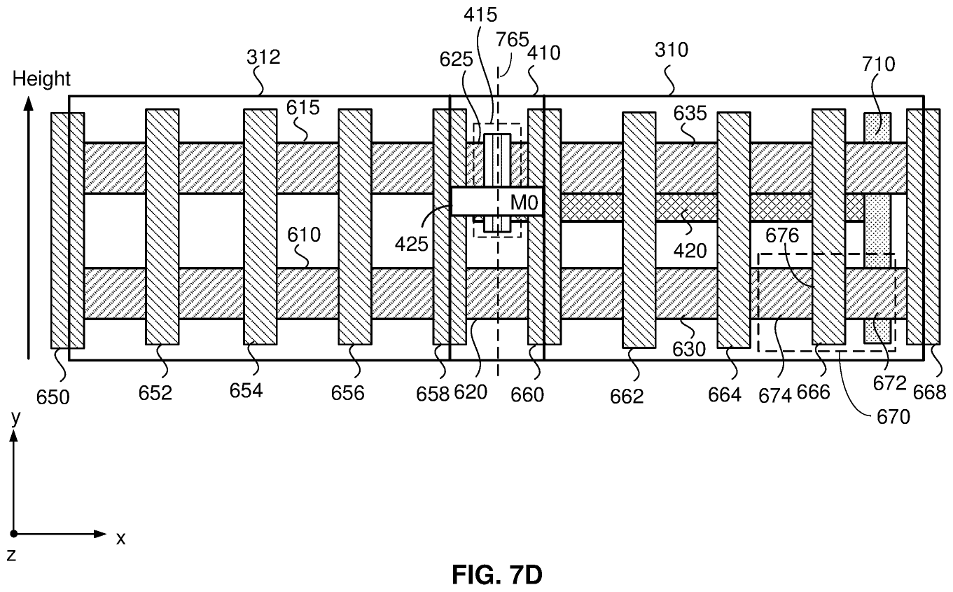

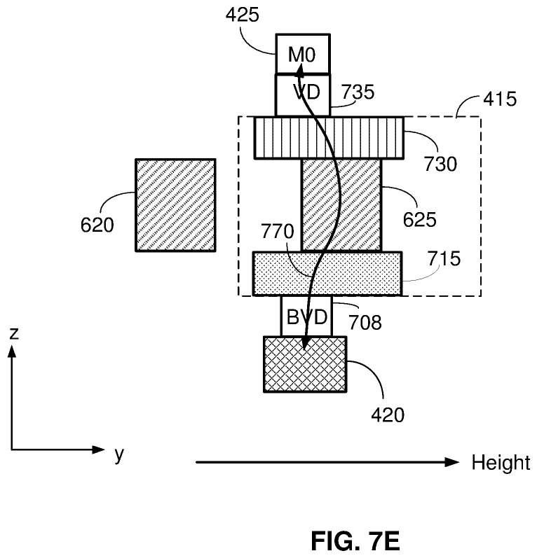

An exemplary implementation of the pass-through structure 415 will now be discussed with reference to FIGS. 7A to 7E according to certain aspects.

FIG. 7A shows a top view of an example of the backside metal routing 420 extending from the first cell 310 to the pass-through structure 415, and passing under the first cell 310. The diffusion regions 610, 615, 620, 625, 630, and 635 are shown with dotted lines in FIG. 7A in order to show the backside metal routing 420 more clearly. FIG. 7A also shows an example of a first backside via 705 (e.g., BVD) disposed on one end of the backside metal routing 420, and a second backside via 708 (e.g., BVD) disposed on another end of the backside metal routing 420 beneath the pass-through structure 415.

FIG. 7B shows an example of a first backside contact 710 (e.g., BSC) extending in the y direction under the first diffusion region 630 and the second diffusion region 635. In this example, the first backside contact 710 is disposed between the first backside via 705 (shown in FIG. 7A) and a bottom surface of the first diffusion region 630. The first backside contact 710 is also disposed between the first backside via 705 and a bottom surface of the second diffusion region 635. Thus, in this example, the first diffusion region 630 and the second diffusion region 635 are coupled to the backside metal routing 420 through the first backside via 705 and the first backside contact 710. However, it is to be appreciated that the present disclosure is not limited to this example.

In another example, the first backside contact 710 may extend under just one of the first diffusion region 630 and the second diffusion region 635. In this example, one of the first diffusion region 630 and the second diffusion regions 635 is coupled to the backside metal routing 420 through the first backside via 705 and the first backside contact 710. In another example, the backside contact 710 may be coupled to a bottom surface of one of the gates 622, 624, and 666 to couple the gate to the backside metal routing 420.

The first backside contact 710 may be coupled to a portion of the first diffusion region 630 (e.g., the portion of the first diffusion region 630 between the gates 666 and 668) providing a source or a drain of a first transistor. The first backside contact 710 may also be coupled to a portion of the second diffusion region 635 (e.g., the portion of the second diffusion region 635 between the gates 666 and 668) providing a source or a drain of a second transistor.

FIG. 7B also shows an example of a second backside contact 715 disposed between a bottom surface of the second diffusion region 625 of the pass-through filler cell 410 and the backside via 708 (shown in FIG. 7A). In this example, the second backside contact 715 and the second diffusion region 625 are part of the pass-through structure 415, in which the second backside contact 715 provides a backside contact for coupling the pass-through structure 415 to the backside metal routing 420.

FIG. 7C shows an example of a topside contact 730 (e.g., MD) disposed on a top surface of the second diffusion region 625. As discussed further below, the topside contact 730 is part of the pass-through structure 415 and provides a contact for coupling the pass-through structure 415 to metal layer M0. FIG. 7C also shows an example of a via 735 (e.g., VD) disposed on the topside contact 730.

FIG. 7D shows an example of the metal line 425 in metal layer M0 extending over the via 735 (shown in FIG. 7C) in the x direction. In this example, the via 735 is disposed between the topside contact 730 and the metal line 425, and couples the topside contact 730 to the metal line 425. FIG. 7D also shows an example in which the first backside contact 710 is coupled to a bottom surface of the first source/drain 672 of the first transistor 670. In this example, the backside metal routing 420 and the pass-through structure 415 provide signal routing for the first source/drain 672. However, it is to be appreciated that the present disclosure is not limited to this example.

FIG. 7E shows a cross-sectional view of the pass-through structure 415 taken along the line 765 in FIG. 7D. As shown in FIG. 7E, the pass-through structure 415 provides a signal path 770 between the backside metal routing 420 in backside metal layer BM0 and the metal line 425 in metal layer M0. In this example, the signal path 770 passes through the second diffusion region 625.

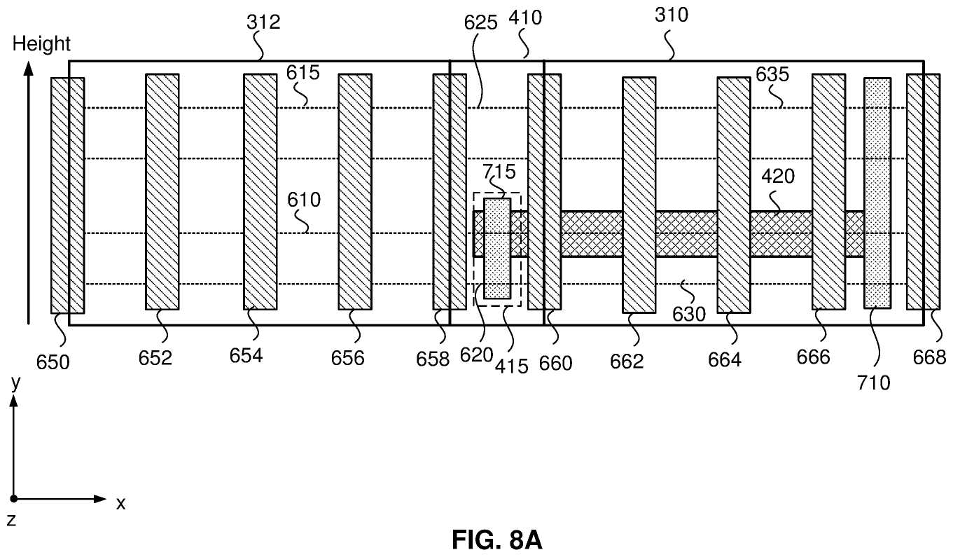

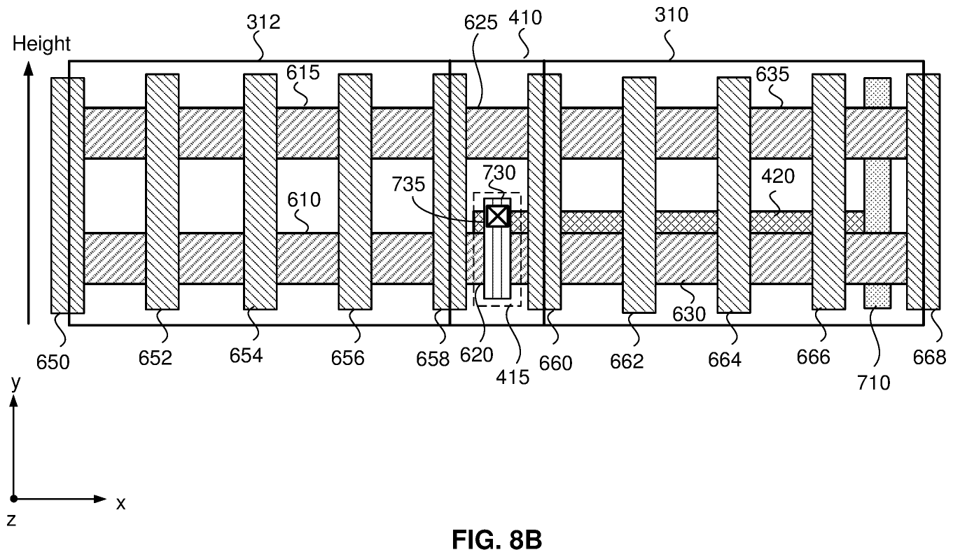

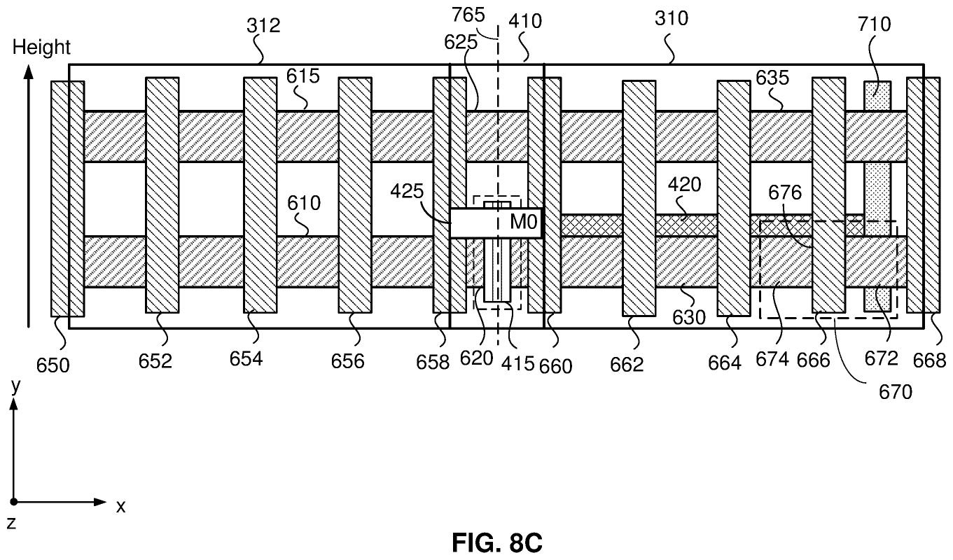

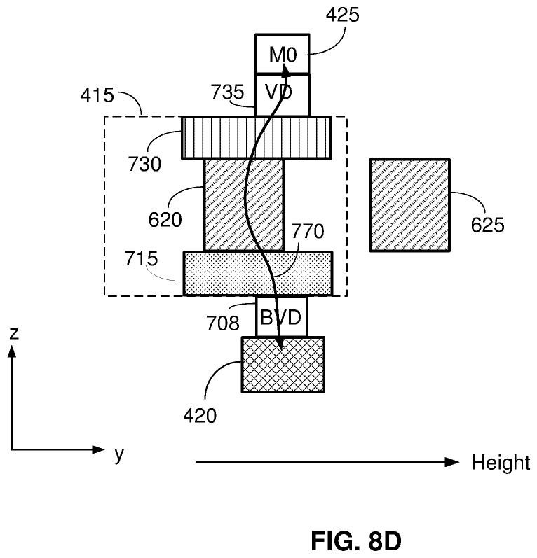

FIGS. 8A to 8D show another exemplary implementation of the pass-through structure 415 in which the signal path 770 passes through the first diffusion region 620 of the pass-through filler cell 410. More particularly, FIG. 8A shows an example in which the second backside contact 715 is disposed between a bottom surface of the first diffusion region 620 of the pass-through filler cell 410 and the backside via 708 (shown in FIG. 7A). In this example, the second backside contact 715 and the first diffusion region 620 are part of the pass-through structure 415, in which the second backside contact 715 provides a backside contact for coupling the pass-through structure 415 to the backside metal routing 420.

FIG. 8B shows an example in which the topside contact 730 (e.g., MD) is disposed on a top surface of the first diffusion region 620. As discussed above, the topside contact 730 is part of the pass-through structure 415 and provides a contact for coupling the pass-through structure 415 to metal layer M0. FIG. 8B also shows an example of the via 735 (e.g., VD) disposed on the topside contact 730.

FIG. 8C shows an example of the metal line 425 in metal layer M0 extending over the via 735 (shown in FIG. 8B) in the x direction. In this example, the via 735 is disposed between the topside contact 730 and the metal line 425, and couples the topside contact 730 to the metal line 425. FIG. 8C also shows an example in which the first backside contact 710 is coupled to a bottom surface of the first source/drain 672 of the first transistor 670. In this example, the backside metal routing 420 and the pass-through structure 415 provide signal routing for the first source/drain 672. However, it is to be appreciated that the present disclosure is not limited to this example.

FIG. 8D shows a cross-sectional view of the pass-through structure 415 taken along the line 765 in FIG. 8C. As shown in FIG. 8D, the pass-through structure 415 provides a signal path 770 between the backside metal routing 420 in backside metal layer BM0 and the metal line 425 in metal layer M0. In this example, the signal path 770 passes through the first diffusion region 620.

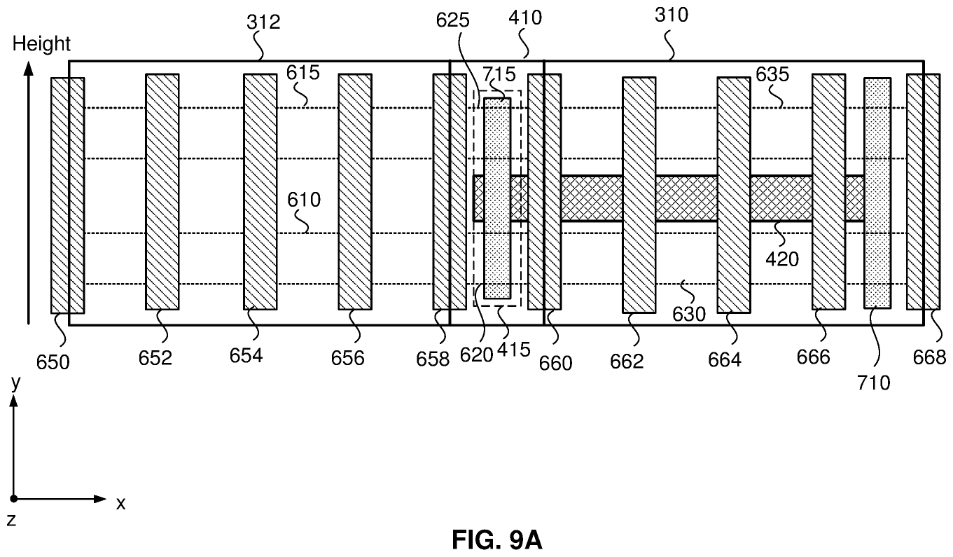

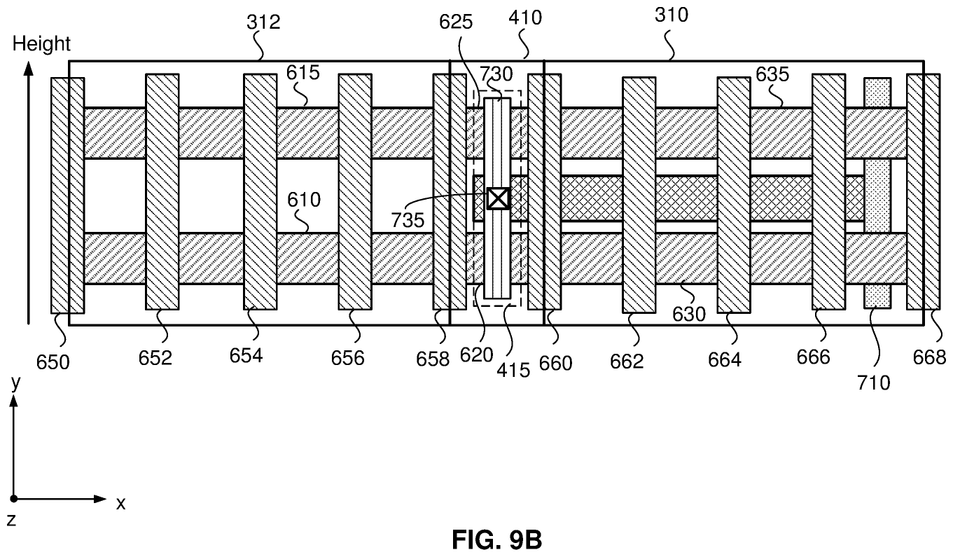

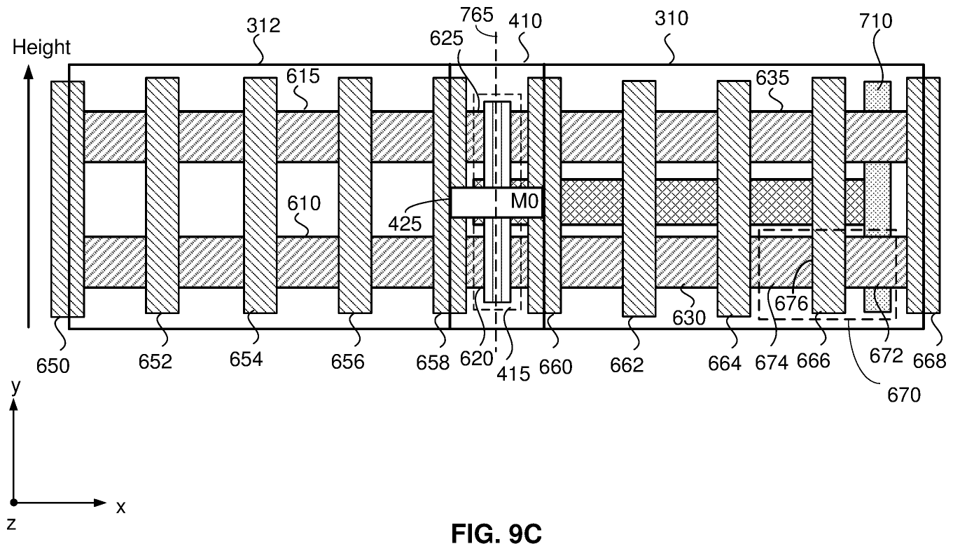

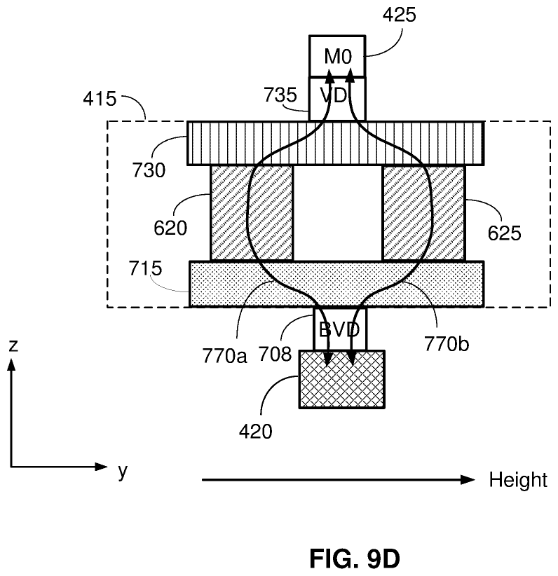

FIGS. 9A to 9D show another exemplary implementation of the pass-through structure 415 including the first diffusion region 620 and the second diffusion region 625. More particularly, FIG. 9A shows an example in which the second backside contact 715 extends in the y direction under the first diffusion region 620 and the second diffusion region 625 of the pass-through filler cell 410. The second backside contact 715 is disposed between the bottom surface of the first diffusion region 620 and the backside via 708. The second backside contact 715 is also disposed between the bottom surface of the second diffusion region 625 and the backside via 708. In this example, the second backside contact 715, the first diffusion region 620, and the second diffusion region 625 are part of the pass-through structure 415, in which the second backside contact 715 provides a backside contact for coupling the pass-through structure 415 to the backside metal routing 420.

FIG. 9B shows an example in which the topside contact 730 (e.g., MD) extends in the y-direction over the first diffusion region 620 and the second diffusion region 625, and is disposed on the top surface of the first diffusion region 620 and the top surface of the second diffusion 625. As discussed above, the topside contact 730 is part of the pass-through structure 415 and provides a contact for coupling the pass-through structure 415 to metal layer M0. FIG. 9B also shows an example of the via 735 (e.g., VD) disposed on the topside contact 730.

FIG. 9C shows an example of the metal line 425 in metal layer M0 extending over the via 735 (shown in FIG. 9B) in the x direction. In this example, the via 735 is disposed between the topside contact 730 and the metal line 425, and couples the topside contact 730 to the metal line 425. FIG. 9C also shows an example in which the first backside contact 710 is coupled to a bottom surface of the first source/drain 672 of the first transistor 670. In this example, the backside metal routing 420 and the pass-through structure 415 provide signal routing for the first source/drain 672. However, it is to be appreciated that the present disclosure is not limited to this example.

FIG. 9D shows a cross-sectional view of the pass-through structure 415 taken along the line 765 in FIG. 9C. As shown in FIG. 9D, the pass-through structure 415 provides a first signal path 770a and a second signal path 770b between the backside metal routing 420 in backside metal layer BM0 and the metal line 425 in metal layer M0. In this example, the first signal path 770a passes through the first diffusion region 620, and the second signal path 770b passes through the second diffusion region 625. The first and second signal paths 770a and 770b provide two parallel signal paths that help reduce resistance (and hence reduce IR drop) between the backside metal routing 420 in backside metal layer BM0 and the metal line 425 in metal layer M0.

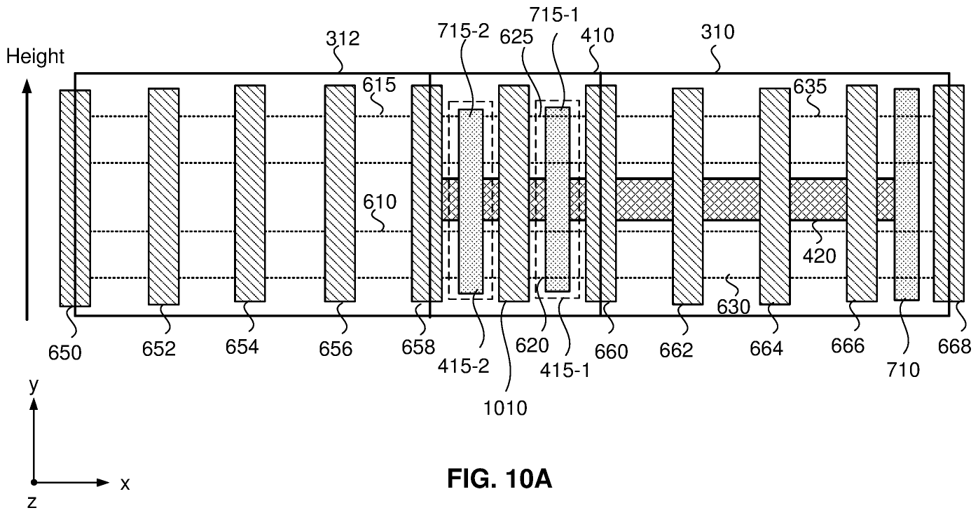

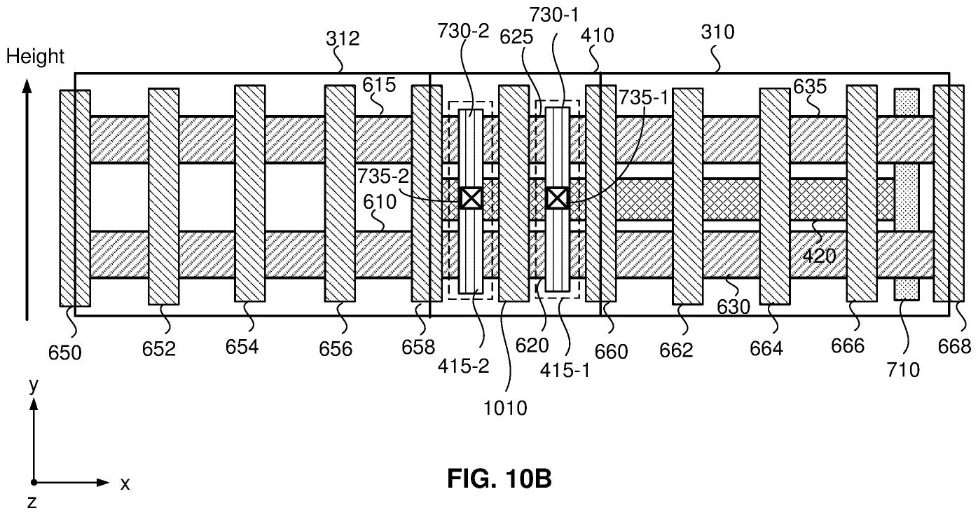

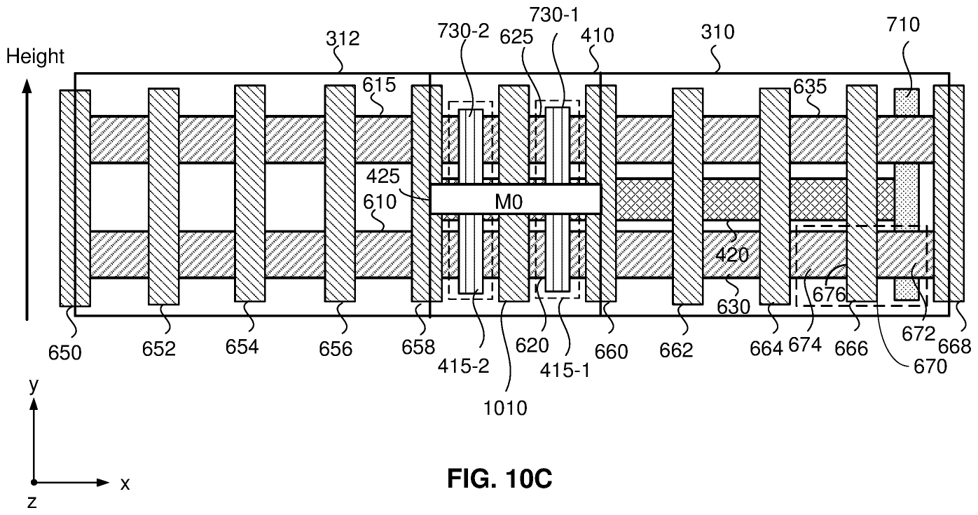

In certain aspects, the pass-through filler cell 410 may include multiple instances of the pass-through structure 415 coupled in parallel to reduce resistance between the backside metal routing 420 in backside metal layer BM0 and the metal line 425 in metal layer M0. In this regard, FIG. 10A shows an example in which the pass-through filler cell 410 includes a first pass-through structure 415-1 and a second pass-through structure 415-2. Each of the pass-through structures 415-1 and 415-2 is a separate instance of the pass-through structure 415, and each of the pass-through structures 415-1 and 415-2 may be implemented using any one of the exemplary implementations of the pass-through structure 415 shown in FIGS. 7A to 7E, 8A to 8D, and 9A to 9D. In this example, the backside metal routing 420 extends under the first pass-through structure 415-1 and the second pass-through structure 415-2 and is coupled to both the first pass-through structure 415-1 and the second pass-through structure 415-2. The first pass-through structure 415-1 and the second pass-through structure 415-2 may be considered part of one pass-through structure including the first pass-through structure 415-1 and the second pass-through structure 415-2

FIG. 10A shows an example in which the first pass-through structure 415-1 includes a second backside contact 715-1 that extends in the y direction under the first diffusion region 620 and the second diffusion region 625 of the pass-through filler cell 410. The second backside contact 715-1 is coupled to the bottom surface of the first diffusion region 620, the bottom surface of the second diffusion region 625, and the backside metal routing 420 (e.g., through a respective backside via BVD).

The second pass-through structure 415-2 includes a third backside contact 715-2 that extends in the y direction under the first diffusion region 620 and the second diffusion region 625 of the pass-through filler cell 410. The third backside contact 715-2 is coupled to the bottom surface of the first diffusion region 620, the bottom surface of the second diffusion region 625, and the backside metal routing 420 (e.g., through a respective backside via BVD).

In this example the pass-through filler cell 410 includes a gate 1010 between the first pass-through structure 415-1 and the second pass-through structure 415-2. The gate 1010 may be a non-functioning gate that is placed in the pass-through filler cell 410 to maintain a uniform pitch between gates on the chip 100. In this example, the pass-through filler cell 410 may have a length in the x direction that is approximately twice the length of the example of the pass-through filler cell 410 shown in FIGS. 7A to 7E, 8A to 8D, and 9A to 9D. The gate 1010 may also be referred to as a filler gate since the gate 1010 is in the pass-through filler cell. The gate 1010 may include polysilicon, a gate metal, or another gate material.

FIG. 10B shows an example in which the first pass-through structure 415-1 includes a first topside contact 730-1 (e.g., MD) extending in the y-direction over the first diffusion region 620 and the second diffusion region 625. The first topside contact 730-1 is disposed on the top surface of the first diffusion region 620 and the top surface of the second diffusion 625. FIG. 10B also shows a first topside via 735-1 (e.g., VD) disposed on the first topside contact 730-1.

FIG. 10B also shows an example in which the second pass-through structure 415-2 includes a second topside contact 730-2 (e.g., MD) extending in the y-direction over the first diffusion region 620 and the second diffusion region 625. The second topside contact 730-2 is disposed on the top surface of the first diffusion region 620 and the top surface of the second diffusion 625. FIG. 10B also shows a second topside via 735-2 (e.g., VD) disposed on the second topside contact 730-2. The second topside via 735-2 is aligned with the first topside via 735-1 in the y direction in this example.

FIG. 10C shows an example of the metal line 425 in metal layer M0 extending over the vias 735-1 and 735-2 (shown in FIG. 10B) in the x direction. In this example, the first topside via 735-1 is disposed between the first topside contact 730-1 and the metal line 425, and couples the first topside contact 730-1 to the metal line 425. The second topside via 735-2 is disposed between the second topside contact 730-2 and the metal line 425, and couples the second topside contact 730-2 to the metal line 425. FIG. 10C also shows an example in which the first backside contact 710 is coupled to a bottom surface of the first source/drain 672 of the first transistor 670. In this example, the backside metal routing 420 and the pass-through structures 415-1 and 415-2 provide signal routing for the first source/drain 672. However, it is to be appreciated that the present disclosure is not limited to this example.

Thus, the metal line 425 extends over the first pass-through structure 415-1 and the second pass-through structure 415-2 and is coupled to both the first pass-through structure 415-1 and the second pass-through structure 415-2. As aresult, the first pass-through structure 415-1 and the second pass-through structure 415-2 provide parallel signal paths between the backside metal routing 420 in backside metal layer BM0 and the metal line 425 in metal layer M0.

Although each of the pass-through structures 415-1 to 415-2 pass through both of the diffusion regions 620 and 625 in the example shown in FIGS. 10A to 10C, it is to be appreciated, that in other implementations, each of the pass-through structures 415-1 to 415-2 may pass through just one of the diffusion regions 620 and 625. For example, each of the pass-through structures 415-1 to 415-2 may be implemented with the exemplary implementation shown in FIGS. 7A to 7E or the exemplary implementation shown in FIGS. 8A to 8D.

It is to be appreciated that the pass-through filler cell 410 is not limited to the example of two pass-through structures and may include additional pass-through structures coupled in parallel between the backside metal routing 420 in backside metal layer BM0 and the metal line 425 in metal layer M0.

Although the pass-through filler cell 410 is located between the first cell 310 and the second cell 312 in the example shown in FIGS. 7A to 7D, FIGS. 8A to 8D, FIGS. 9A to 9D, and FIGS. 10A to 10C, it is to be appreciated that the present disclosure is not limited to this example. For example, the pass-through filler cell 410 may be located between the third cell 314 and the fourth cell 316 (shown in FIGS. 5A and 5B). In this example, the backside metal routing 420 also extends under the third cell 314 to reach the pass-through filler cell 410. For example, the backside metal routing 420 may extend under the transistor 450 in the third cell 314 shown in FIG. 5B.

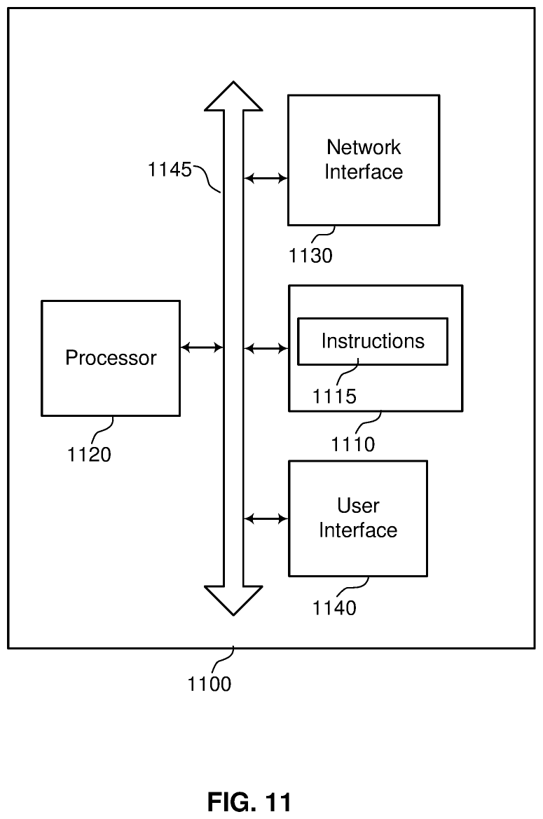

In certain aspects, the exemplary layouts discussed above may be determined using a computer system. In this regard, FIG. 11 illustrates a computer system 1100 that may be used to determine layouts for the chip 100 according to certain aspects. The computer system 1100 may include a processor 1120, a memory 1110, a network interface 1130, and a user interface 1140. These components may be in electronic communication via one or more buses 1145.

The memory 1110 may store instructions 1115 that are executable by the processor 1120 to cause the computer system 1100 to perform one or more of the operations described herein. The processor 1120 may include a general-purpose processor, a digital signal processor (DSP), a central processing unit (CPU), a microcontroller, an application specific integrated circuit (ASIC), a field programmable gate array (FPGA), a programmable logic device, a discrete gate or transistor logic component, a discrete hardware component, or any combination thereof.

The memory 1110 may include, by way of example, random access memory (RAM), flash memory, read only memory (ROM), programmable read only memory (PROM), erasable programmable read only memory (EPROM), electrically erasable programmable read only memory (EEPROM), registers, magnetic disks, optical disks, hard drives, or any other suitable storage medium, or any combination thereof. The memory 1110 may also store a cell library including files specifying layouts for various cells that may be placed on the chip 100 including layouts of pass-through filler cells (e.g., pass-through filler cell 410).

The network interface 1130 is configured to interface the computer system 1100 with one or more other devices. The user interface 1140 may be configured to receive data from a user (e.g., via keypad, mouse, etc.) and provide the data to the processor 1120. The user interface 1140 may also be configured to output data from the processor 1120 to the user (e.g., via a display, a speaker, etc.).

Implementation examples are described in the following numbered clauses:

1. A chip, comprising:
a first transistor comprising:
   a first source/drain;
   a second source/drain;
   a gate between the first source/drain and the second source/drain; and
   a first backside contact coupled to a bottom surface of the first source/drain;
a pass-through structure comprising:
   a first diffusion region extending in a first direction;
   a second backside contact coupled to a bottom surface of the first diffusion region; and
   a topside contact coupled to a top surface of the first diffusion region; and
a backside metal routing coupled between the first backside contact and the second backside contact.

2. The chip of clause 1, further comprising a second transistor between the first transistor and the pass-through structure, wherein the backside metal routing extends under the second transistor.

3. The chip of clause 1 or 2, wherein the backside metal routing includes a backside metal line extending in the first direction.

4. The chip of any one of clauses 1 to 3, further comprising a first topside metal line extending in the first direction, wherein the topside contact is coupled to the first topside metal line.

5. The chip of clause 4, further comprising a second topside metal line extending in a second direction perpendicular to the first direction, wherein the second topside metal line is coupled to the first topside metal line.

6. The chip of clause 5, wherein the first topside metal line is formed from a first metal layer, and the second topside metal line is formed from a second metal layer above the first metal layer.

7. The chip of any one of clauses 1 to 6, further comprising:
a first backside via disposed between the first backside contact and the backside metal routing; and
a second backside via disposed between the second backside contact and the backside metal routing.

8. The chip of any one of clauses 1 to 7, wherein the pass-through structure further comprises a second diffusion region, the second backside contact is coupled to a bottom surface of the second diffusion region, and the topside contact is coupled to a top surface of the second diffusion region.

9. The chip of clause 8, wherein the first diffusion region and the second diffusion region are spaced apart in a second direction perpendicular to the first direction.

10. The chip of clause 9, wherein the first diffusion region is a p-type diffusion region and the second diffusion region is an n-type diffusion region.

11. The chip of clause 9, wherein the first diffusion region is an n-type diffusion region and the second diffusion region is a p-type diffusion region.

12. A chip, comprising:
a first transistor comprising:
   a first source/drain;
   a second source/drain;
   a gate between the first source/drain and the second source/drain; and
   a backside contact coupled to a bottom surface of the first source/drain;
pass-through structures;
a backside metal routing coupled to the backside contact and extending under the first transistor to the pass-through structures; and
a topside metal line extending over the pass-through structures, wherein the pass-through structures are coupled in parallel between the backside metal routing and the topside metal line, and each of the pass-through structures provides a respective signal path between the backside metal routing and the topside metal line.

13. The chip of clause 12, further comprising a second transistor between the first transistor and the pass-through structures, wherein the backside metal routing extends under the second transistor.

14. The chip of clause 12 or 13, wherein the backside metal routing includes a backside metal line.

15. A chip, comprising:
a first transistor comprising:
   a first source/drain;
   a second source/drain;
   a first gate between the first source/drain and the second source/drain; and
   a first backside contact coupled to a bottom surface of the first source/drain; and
a pass-through structure comprising:
   a first diffusion region extending in a first direction;
   a second backside contact coupled to a bottom surface of first diffusion region;
   a first topside contact coupled to a top surface of the first diffusion region;
   a third backside contact coupled to the bottom surface of the first diffusion region; and
   a second topside contact coupled to the top surface of the first diffusion region;
a backside metal routing coupled to the first backside contact, the second backside contact, and the third backside contact, wherein the backside metal routing extends under the first transistor to the pass-through structure; and
a topside metal line extending in the first direction, wherein the topside metal line is coupled to the first topside contact and the second topside contact.

16. The chip of clause 15, further comprising a second transistor between the first transistor and the pass-through structure, wherein the backside metal routing extends under the second transistor.

17. The chip of clause 15 or 16, wherein the backside metal routing includes a backside metal line.

18. The chip of any one of clauses 15 to 17, wherein the pass-through structure further comprises a second gate between the first topside contact and the second topside contact.

19. The chip of any one of clauses 15 to 18, wherein the pass-through structure further comprises a second diffusion region extending in the first direction, the second backside contact is coupled to a bottom surface of the second diffusion region, the third backside contact is coupled to the bottom surface of the second diffusion region, the first topside contact is coupled to a top surface of the second diffusion region, and the second topside contact is coupled to the top surface of the second diffusion region.

20. The chip of clause 19, wherein the first diffusion region and the second diffusion region are spaced apart in a second direction perpendicular to the first direction.

21. The chip of clause 20, wherein the first diffusion region is a p-type diffusion region and the second diffusion region is an n-type diffusion region.

22. The chip of clause 20, wherein the first diffusion region is an n-type diffusion region and the second diffusion region is a p-type diffusion region.

23. A chip, comprising:
a first cell comprising:
   a first diffusion region extending in a first direction;
   gates formed over the first diffusion region, wherein each of the gates is elongated and extends in a second direction perpendicular to the first direction; and
   a first backside contact coupled to a bottom surface of the first diffusion region;
a pass-through filler cell comprising:
   a second diffusion region;
   a second backside contact coupled to a bottom surface of the second diffusion region; and
   a topside contact coupled to a top surface of the second diffusion region; and
a backside metal routing coupled between the first backside contact and the second backside contact.

24. The chip of clause 23, further comprising a second cell between the first cell and the pass-through filler cell, wherein the backside metal routing extends under the second cell.

25. The chip of clause 23 or 24, further comprising a first topside metal line extending in the first direction, wherein the topside contact is coupled to the first topside metal line.

26. The chip of clause 25, further comprising a second topside metal line extending in the second direction, wherein the second topside metal line is coupled to the first topside metal line.

27. The chip of any one of clauses 23 to 26, further comprising:
a first backside via disposed between the first backside contact and the backside metal routing; and
a second backside via disposed between the second backside contact and the backside metal routing.

28. The chip of any one of clauses 23 to 27, wherein the pass-through filler cell further comprises a third diffusion region, the second backside contact is coupled to a bottom surface of the third diffusion region, and the topside contact is coupled to a top surface of the third diffusion region.

29. The chip of clause 28, wherein the second diffusion region and the third diffusion region are spaced apart in the second direction.

30. A chip, comprising:
a first cell comprising:
   a first diffusion region extending in a first direction;
   gates formed over the first diffusion region, wherein each of the gates is elongated and extends in a second direction perpendicular to the first direction; and
   a first backside contact coupled to a bottom surface of the first diffusion region;
a pass-through filler cell comprising:
   a second diffusion region;
   a second backside contact coupled to a bottom surface of the second diffusion region;
   a first topside contact coupled to a top surface of the second diffusion region;
   a third backside contact coupled to the bottom surface of the second diffusion region; and
   a second topside contact coupled to the top surface of the second diffusion region;
a backside metal routing coupled to the first backside contact, the second backside contact, and the third backside contact, wherein the backside metal routing extends under the first cell to the pass-through filler cell; and
a topside metal line extending in the first direction, wherein the topside metal line is coupled to the first topside contact and the second topside contact.

31. The chip of clause 30, further comprising a second cell between the first cell and the pass-through filler cell, wherein the backside metal routing extends under the second cell.

32. The chip of clause 30 or 31, wherein the backside metal routing includes a backside metal line extending in the first direction.

33. The chip of any one of clauses 30 to 32, wherein the pass-through filler cell further comprises a filler gate extending in the second direction, wherein the filler gate is between the first topside contact and the second topside contact.

34. The chip of any one of clauses 30 to 33, wherein the pass-through filler cell further comprises a third diffusion region extending in the first direction, the second backside contact is coupled to a bottom surface of the third diffusion region, the third backside contact is coupled to the bottom surface of the third diffusion region, the first topside contact is coupled to a top surface of the third diffusion region, and the second topside contact is coupled to the top surface of the third diffusion region.

35. The chip of clause 34, wherein the second diffusion region and the third diffusion region are spaced apart in the second direction.

36. The chip of clause 35, wherein the second diffusion region is a p-type diffusion region and the third diffusion region is an n-type diffusion region.

37. The chip of clause 35, wherein the second diffusion region is an n-type diffusion region and the third diffusion region is a p-type diffusion region.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value. The x direction may also be referred to as a first direction and the y direction may also be referred to as a second direction that is perpendicular to the first direction.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first transistor comprising:
a first source/drain;
a second source/drain;
a gate between the first source/drain and the second source/drain; and
a first backside contact coupled to a bottom surface of the first source/drain;
a pass-through structure comprising:
a first diffusion region extending in a first direction;
a second backside contact coupled to a bottom surface of the first diffusion region; and
a topside contact coupled to a top surface of the first diffusion region; and
a backside metal routing coupled between the first backside contact and the second backside contact.

2. The chip of claim 1, further comprising a second transistor between the first transistor and the pass-through structure, wherein the backside metal routing extends under the second transistor.

3. The chip of claim 1, wherein the backside metal routing includes a backside metal line extending in the first direction.

4. The chip of claim 1, further comprising a first topside metal line extending in the first direction, wherein the topside contact is coupled to the first topside metal line.

5. The chip of claim 4, further comprising a second topside metal line extending in a second direction perpendicular to the first direction, wherein the second topside metal line is coupled to the first topside metal line.

6. The chip of claim 5, wherein the first topside metal line is formed from a first metal layer, and the second topside metal line is formed from a second metal layer above the first metal layer.

7. The chip of claim 1, further comprising:
a first backside via disposed between the first backside contact and the backside metal routing; and
a second backside via disposed between the second backside contact and the backside metal routing.

8. The chip of claim 1, wherein the pass-through structure further comprises a second diffusion region, the second backside contact is coupled to a bottom surface of the second diffusion region, and the topside contact is coupled to a top surface of the second diffusion region.

9. The chip of claim 8, wherein the first diffusion region and the second diffusion region are spaced apart in a second direction perpendicular to the first direction.

10. The chip of claim 9, wherein the first diffusion region is a p-type diffusion region and the second diffusion region is an n-type diffusion region.

11. The chip of claim 9, wherein the first diffusion region is an n-type diffusion region and the second diffusion region is a p-type diffusion region.

12. A chip, comprising:
a first transistor comprising:
a first source/drain;
a second source/drain;
a gate between the first source/drain and the second source/drain; and
a backside contact coupled to a bottom surface of the first source/drain;
pass-through structures;
a backside metal routing coupled to the backside contact and extending under the first transistor to the pass-through structures; and
a topside metal line extending over the pass-through structures, wherein the pass-through structures are coupled in parallel between the backside metal routing and the topside metal line, and each of the pass-through structures provides a respective signal path between the backside metal routing and the topside metal line.

13. The chip of claim 12, further comprising a second transistor between the first transistor and the pass-through structures, wherein the backside metal routing extends under the second transistor.

14. The chip of claim 12, wherein the backside metal routing includes a backside metal line.

15. A chip, comprising:
a first transistor comprising:
a first source/drain;
a second source/drain;
a first gate between the first source/drain and the second source/drain; and
a first backside contact coupled to a bottom surface of the first source/drain; and
a pass-through structure comprising:
a first diffusion region extending in a first direction;
a second backside contact coupled to a bottom surface of first diffusion region;
a first topside contact coupled to a top surface of the first diffusion region;
a third backside contact coupled to the bottom surface of the first diffusion region; and
a second topside contact coupled to the top surface of the first diffusion region;
a backside metal routing coupled to the first backside contact, the second backside contact, and the third backside contact, wherein the backside metal routing extends under the first transistor to the pass-through structure; and
a topside metal line extending in the first direction, wherein the topside metal line is coupled to the first topside contact and the second topside contact.

16. The chip of claim 15, further comprising a second transistor between the first transistor and the pass-through structure, wherein the backside metal routing extends under the second transistor.

17. The chip of claim 15, wherein the backside metal routing includes a backside metal line.

18. The chip of claim 15, wherein the pass-through structure further comprises a second gate between the first topside contact and the second topside contact.

19. The chip of claim 15, wherein the pass-through structure further comprises a second diffusion region extending in the first direction, the second backside contact is coupled to a bottom surface of the second diffusion region, the third backside contact is coupled to the bottom surface of the second diffusion region, the first topside contact is coupled to a top surface of the second diffusion region, and the second topside contact is coupled to the top surface of the second diffusion region.

20. The chip of claim 19, wherein the first diffusion region and the second diffusion region are spaced apart in a second direction perpendicular to the first direction.

21. The chip of claim 20, wherein the first diffusion region is a p-type diffusion region and the second diffusion region is an n-type diffusion region.

22. The chip of claim 20, wherein the first diffusion region is an n-type diffusion region and the second diffusion region is a p-type diffusion region.

23. A chip, comprising:
a first cell comprising:
a first diffusion region extending in a first direction;
gates formed over the first diffusion region, wherein each of the gates is elongated and extends in a second direction perpendicular to the first direction; and
a first backside contact coupled to a bottom surface of the first diffusion region;
a pass-through filler cell comprising:
a second diffusion region;
a second backside contact coupled to a bottom surface of the second diffusion region; and
a topside contact coupled to a top surface of the second diffusion region; and
a backside metal routing coupled between the first backside contact and the second backside contact.

24. The chip of claim 23, further comprising a second cell between the first cell and the pass-through filler cell, wherein the backside metal routing extends under the second cell.

25. The chip of claim 23, further comprising a first topside metal line extending in the first direction, wherein the topside contact is coupled to the first topside metal line.

26. The chip of claim 25, further comprising a second topside metal line extending in the second direction, wherein the second topside metal line is coupled to the first topside metal line.

27. The chip of claim 23, further comprising:
a first backside via disposed between the first backside contact and the backside metal routing; and
a second backside via disposed between the second backside contact and the backside metal routing.

28. The chip of claim 23, wherein the pass-through filler cell further comprises a third diffusion region, the second backside contact is coupled to a bottom surface of the third diffusion region, and the topside contact is coupled to a top surface of the third diffusion region.

29. The chip of claim 28, wherein the second diffusion region and the third diffusion region are spaced apart in the second direction.
